(19) United States
(12) Patent Application Publication
(10) Pub. No.: US 2007/0190751 A1
(43) Pub. Date: Aug. 16, 2007

(54) Semiconductor fuses and methods for fabricating and programming the same

(76) Inventor: Kenneth W. Marr, Boise, ID (US)

Correspondence Address: TRASK BRITT, P.C./ MICRON TECHNOLOGY, P.O. BOX 2550, SALT LAKE CITY, UT, 84110, US

(21) Appl. No.: 11/725,296

(22) Filed: Mar. 19, 2007

Related U.S. Application Data
(63) Continuation of application No. 09/277,893, filed on Mar. 29, 1999.

(51) Int. Cl. H01L 21/326; H01L 21/82; H01L 29/00

(52) U.S. Cl. 438/467; 257/529; 438/132

(57) ABSTRACT

A fuse for use in semiconductor devices, semiconductor devices including the fuse, methods of fabricating the fuse, and methods of using the fuse. The fuse includes terminals and a programmable region between the terminals. The programmable region may have less mass than the terminals. The programmable region may include metal silicide, which is rendered discontinuous by agglomeration or melting when a programming current is applied to one of the terminals. Construction of the fuse or features over the fuse may prevent programming of the fuse with a laser.

### CROSS-REFERENCE TO RELATED APPLICATION

This application is a continuation of application Ser. No. 09/277,893, filed Mar. 29, 1999, pending.

### BACKGROUND OF THE INVENTION

1. Field of the Invention

The present invention relates generally to the design and fabrication of semiconductor devices. Specifically, the present invention relates to fuses, semiconductor devices that include such fuses, and methods of making and using the fuses. In particular, the present invention relates to metal silicide fuses and to methods of fabricating metal silicide fuses.

2. Background of Related Art

Computers typically include various types of devices which store data, such as memory devices. One type of memory device is a read-only memory (“ROM”) device in which data is permanently stored, the programming of which cannot be overwritten or otherwise altered. Thus, ROM devices are useful whenever unalterable data or instructions may be employed or are required. ROM devices are also nonvolatile devices, meaning that the data is not destroyed when power to these devices is shut off. ROM devices are typically programmed during the fabrication thereof by making permanent electrical connections in selected portions of the memory device. Accordingly, the programming of ROM devices, somewhat undesirably, cannot be changed. If a new program is desired, the ROM must be configured to be wired with the new program.

Another type of memory device that may be employed in a computer is a programmable read-only memory (“PROM”) device. Unlike ROM devices, PROM devices are programmable after their design and fabrication. To render them programmable, some PROM devices are provided with an electrical connection in the form of a fusible link, which is also typically referred to as a fuse. Exemplary fuses that may be employed in semiconductor devices are disclosed in U.S. Pat. Nos. 5,264,725, 4,670,970, 5,661,323, 5,652,175, 5,618,750, 5,578,517, and 3,783,506. One type of conventional fuse includes a metal or polysilicon layer which is narrowed or “necked down” in one region. To blow the fuse, a relatively high current is driven through the metal or polysilicon layer. The current heats the metal or polysilicon above its melting point, thereby breaking the conductive link by making the metal or polysilicon discontinuous. Usually, the conductive link breaks in the narrowed region because the current density and temperature are highest in that region. The PROM device is thus programmed to a selected one of a pair of conductivity or voltage patterns, which correspond to either a 1 or a 0, which is the data stored in a particular cell of the memory device associated with the fuse.

Rather than employing an electrical current, a laser can be employed to blow the fuses. sing lasers instead of electrical current to blow fuses, however, has become more difficult as the size of memory devices decreases. As memory devices decrease in size and the degree or density of integration increases, the critical dimensions (e.g., fuse pitch) of memory cells become smaller. The availability of lasers suitable to blow the fuse is limited since the diameter of the laser beam should not be larger than the fuse pitch. Thus, when lasers are the desired means of programming fuses, the fuse pitch and, therefore, the size of the memory device are dictated by minimum diameters of laser beams obtainable by current laser technology.

The use of electrical currents or lasers to blow fuses may be employed to adapt fuses for a variety of applications, such as redundancy technology. Redundancy technology improves the fabrication yield of high-density memory devices, such as static random access memory (“SRAM”) devices and dynamic random access memory (“DRAM”) devices, by facilitating the replacement of failed memory cells with spare ones by activating redundant circuitry by blowing fuses. As explained above, using laser beams to blow the fuses limits the size and, therefore, the number of memory devices since the diameter of some conventional laser beams is about 5 microns. Using electrical currents instead to blow fuses, therefore, has a greater potential for high-degree integration and decreased size of memory devices.

Programmable fuses could be employed to address a variety of applications in numerous types of semiconductor devices. The use of fuses has, however, been largely confined to memory devices due to some of the inherent problems with conventional fuses. For example, the amount of current or laser beam intensity that may be required to “blow” conventional metal or polysilicon fuses may damage regions and structures of the semiconductor device that are proximate to the fuse.

Thus, there is a need for a fuse that may be fabricated in state of the art semiconductor devices and that may be programmed, or blown, to impart the fuse with a significantly different conductivity than that of an intact fuse without significantly affecting surrounding structures. There is also a need for a fuse that can be fabricated by known semiconductor device fabrication techniques.

### SUMMARY OF THE INVENTION

The present invention includes a fuse for use in semiconductor devices and methods of fabricating the fuse and semiconductor devices including the same. The fuse of the present invention may be disposed over an insulative structure, such as an oxide layer (e.g., a field oxide) of a semiconductor device. The fuse of the present invention is preferably an elongate structure that includes two terminal regions disposed on either side of a central, or conductive, region. The terminal regions of the fuse may be disposed over polysilicon. The central region of the fuse is preferably disposed directly adjacent the underlying insulative structure. Thus, the central region of the fuse may have a lesser conductive material volume than either of the terminal ends. The central region of the fuse may also be narrower in width than the terminal regions. Preferably, the fuse is fabricated from a metal silicide (e.g., tungsten silicide, titanium silicide, tantalum silicide, molybdenum silicide, cobalt silicide, nickel silicide, platinum silicide, lead silicide, etc.) or a polycide.

The insulative layer upon which the fuse of the present invention is disposed may comprise an insulating substrate. As an example, the insulating substrate can be a field oxide region disposed on a silicon substrate or on another semiconductor substrate.

Preferably, the polysilicon that underlies the terminal regions of the fuse is disposed on the insulative structure in discrete regions or portions that are substantially isolated from one another. The inventive fuse may be employed in a circuit of a semiconductor device, either alone or in association with a gate structure or a transistor.

The present invention also includes a method of fabricating a fuse for use in a semiconductor device. The fuse is preferably fabricated adjacent an insulative structure or layer of a semiconductor device, such as a field oxide thereof. Preferably, the fuse is fabricated substantially concurrently with the fabrication of a transistor gate structure of the semiconductor device.

In fabricating the fuse, a layer of conductive material is preferably disposed adjacent the insulative structure or layer. The conductive material of the layer preferably comprises polysilicon. Thus, the polysilicon may be conductively doped. The layer of conductive material may be patterned to define at least two spaced apart regions of the layer of conductive material adjacent the insulative structure. Accordingly, the underlying insulative structure is exposed between the at least two spaced apart regions of the layer of conductive material.

A layer comprising a metal silicide, which is also referred to herein as a fuse layer or as a polycide layer, may be formed by disposing metal silicide on the previously disposed layer of conductive material. Alternatively, adjacent silicon or polysilicon and metal layers may be disposed and annealed to one another to form the layer of metal silicide. The fuse layer may be patterned to define a fuse therefrom. Preferably, regions of the fuse layer that are directly adjacent the insulative structure are defined to be narrower than the regions that overlie the at least two spaced apart regions of the layer of conductive material. The portion of the fuse defined from the fuse layer that is adjacent the insulative structure is referred to herein as the central region, or conductive region, of the fuse. The portions of the fuse layer that are adjacent the layer of conductive material are referred to herein as the terminal regions of the fuse. Preferably, the combined conductive material volume of each terminal region and the conductive material adjacent thereto exceeds the conductive material volume of the central region of the fuse.

By providing spaced apart regions of a layer of conductive material, such as polysilicon adjacent the terminal regions of the fuse, and by disposing a preferably narrower central region of the fuse adjacent an insulative structure exposed between the spaced apart regions and terminal regions of the fuse layer adjacent the layer of conductive material, the fuse of the present invention preferably “blows” at the central region thereof when a programming current is applied to the fuse, thereby yielding an open circuit. The open circuit results as the central region of the fuse agglomerates, melts, or otherwise becomes discontinuous and will, therefore, no longer conduct a significant electrical current between the terminal regions of the fuse.

Other features and advantages of the present invention will become apparent to those of ordinary skill in the art through a consideration of the ensuing description, the accompanying drawings, and the appended claims.

### BRIEF DESCRIPTION OF THE SEVERAL VIEWS OF THE DRAWINGS

The figures presented in conjunction with this description are not actual views of any particular portion of an actual semiconductor device or component, but are merely schematic representations employed to more clearly and fully depict the present invention.

FIGS. 1 and 8 are cross-sectional schematic representations of a preferred embodiment of a process for fabricating a fuse and the resulting fuse in accordance with the method of the present invention;

FIGS. 2-6 illustrate the substantially concurrent fabrication of the fuse and a transistor gate structure; and

FIG. 7 is a schematic representation of a top view of a fuse according to the present invention.

### DETAILED DESCRIPTION OF THE INVENTION

The following description provides specific details of preferred embodiments of the present invention in order to provide the reader with a thorough understanding of the present invention. The skilled artisan, however, would understand that the present invention may be practiced without employing these specific details. Indeed, the present invention can be practiced in conjunction with fabrication techniques conventionally used in the industry.

The process steps and structures described below do not form a complete process flow for fabricating semiconductor devices or for fabricating a completed device. Only the processes and structures that are necessary to provide one of ordinary skill in the art with an understanding of the present invention are described herein.

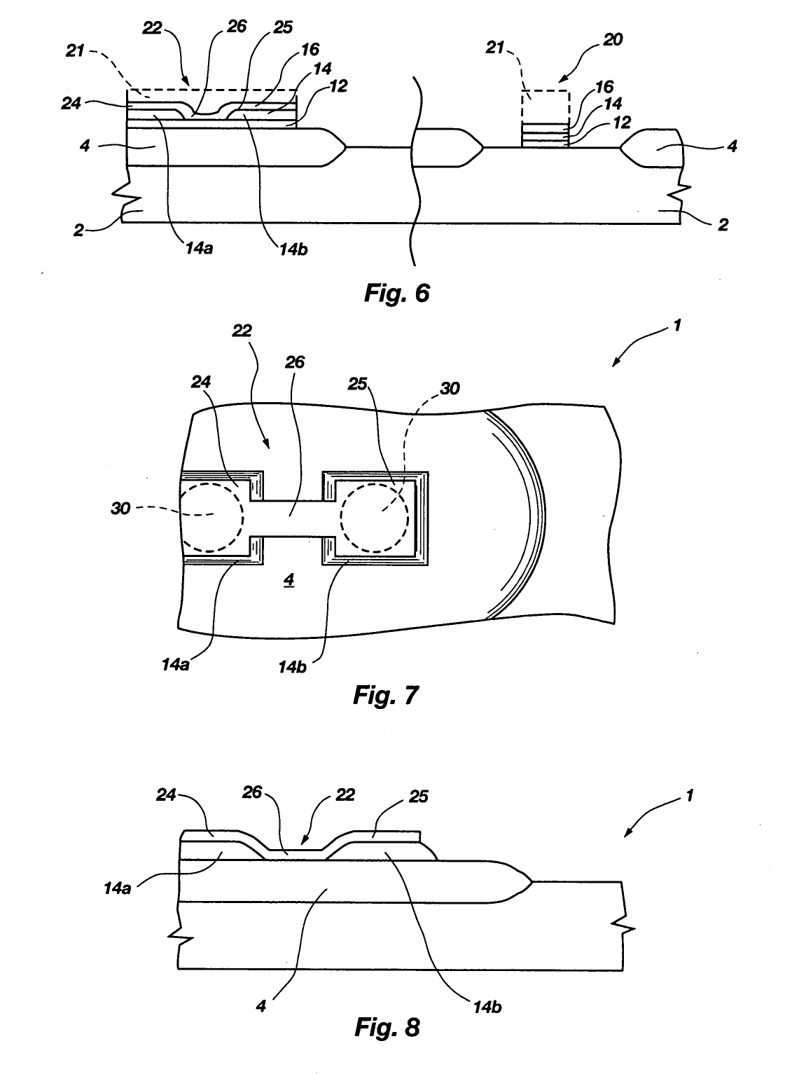

FIGS. 7 and 8 illustrate a preferred embodiment of a fuse 22 according to the present invention. Terminal regions 24 and 25 of fuse 22 each overlie spaced apart regions 14a and 14b of polysilicon or another conductive material. An insulative structure 4 of semiconductor device 1 upon which these spaced apart regions 14a and 14b of conductive material are disposed or another structure or layer of insulative material may be exposed to fuse 22 between spaced apart regions 14a and 14b. A central region 26 of fuse 22 is preferably disposed between terminal regions 24 and 25 and directly adjacent the insulative structure or layer exposed between spaced apart regions 14a and 14b. Terminal regions 24 and 25 are configured to accommodate conductive contacts 30 of a type known in the art, and which facilitate the flow of current across fuse 22. Central region 26 is preferably narrower in width than terminal regions 24 and 25. As central region 26 has a lesser conductive material volume than the terminal regions 24 and 25 and their adjacent conductive regions 14a and 14b, central region 26 will likely “blow” before terminal regions 24 or 25 when fuse 22 is subjected to at least a programming electrical current. Central region 26 will likely “blow” before terminal regions 24 and 25 because, while the same amount of current runs through both the terminal regions 24 and 25 and the central region 26 of fuse 22, there is less volume of conductive material in central region 26 than at each of terminal regions 24 and 25, especially when the volumes of their adjacent regions 14a and 14b of polysilicon are also considered. Consequently, the temperature in central region 26 increases at a faster rate than the temperature in terminal regions 24 and 25, leading to quicker agglomeration, melting, or otherwise induced discontinuity of fuse 22 in central region 26. Moreover, as central region 26 of fuse 22 is disposed directly adjacent an insulative structure or layer (e.g., insulative structure 4), once central region 26 of fuse 22 is “blown” or otherwise rendered discontinuous, substantially no electrical current will be conducted across central region 26 of fuse 22 between terminal region 24 and terminal region 25.

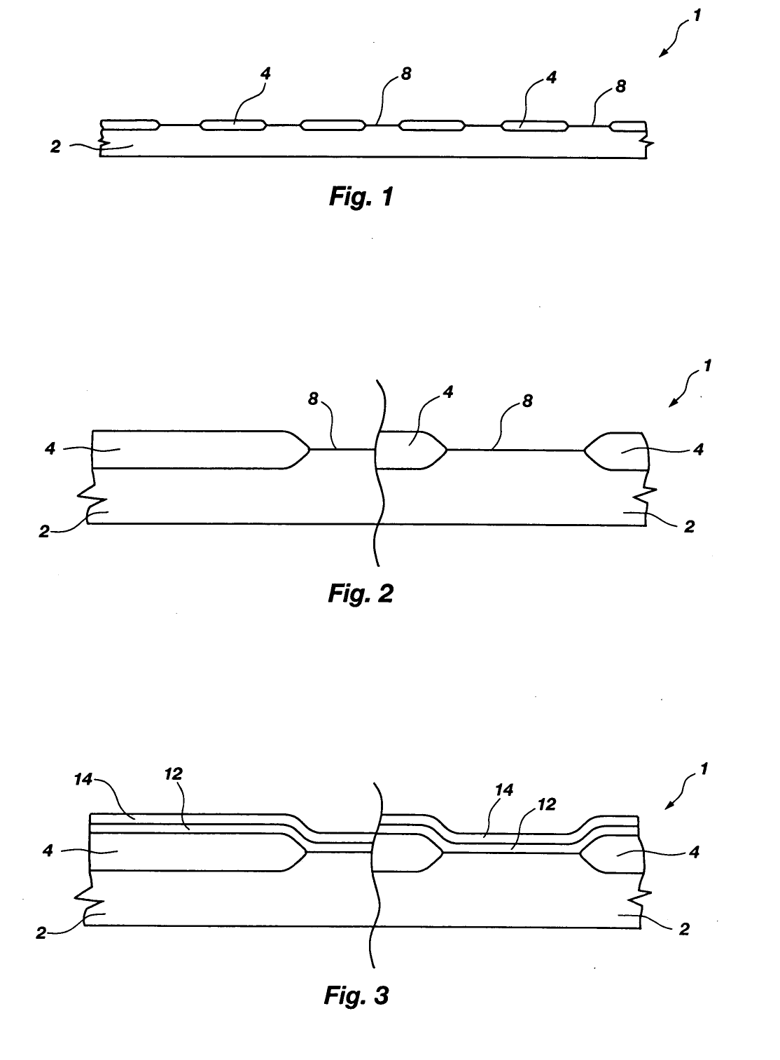

FIGS. 1-8 illustrate an embodiment of a method of fabricating a fuse upon a semiconductor device in accordance with the present invention. The fuse may be fabricated substantially simultaneously with the fabrication of a gate structure of a field effect transistor and may be integrated into the process of fabricating such a gate. It will be understood, however, by those skilled in the art, that other fuses could also be formed by slight modifications of the method described in reference to FIGS. 1-7.

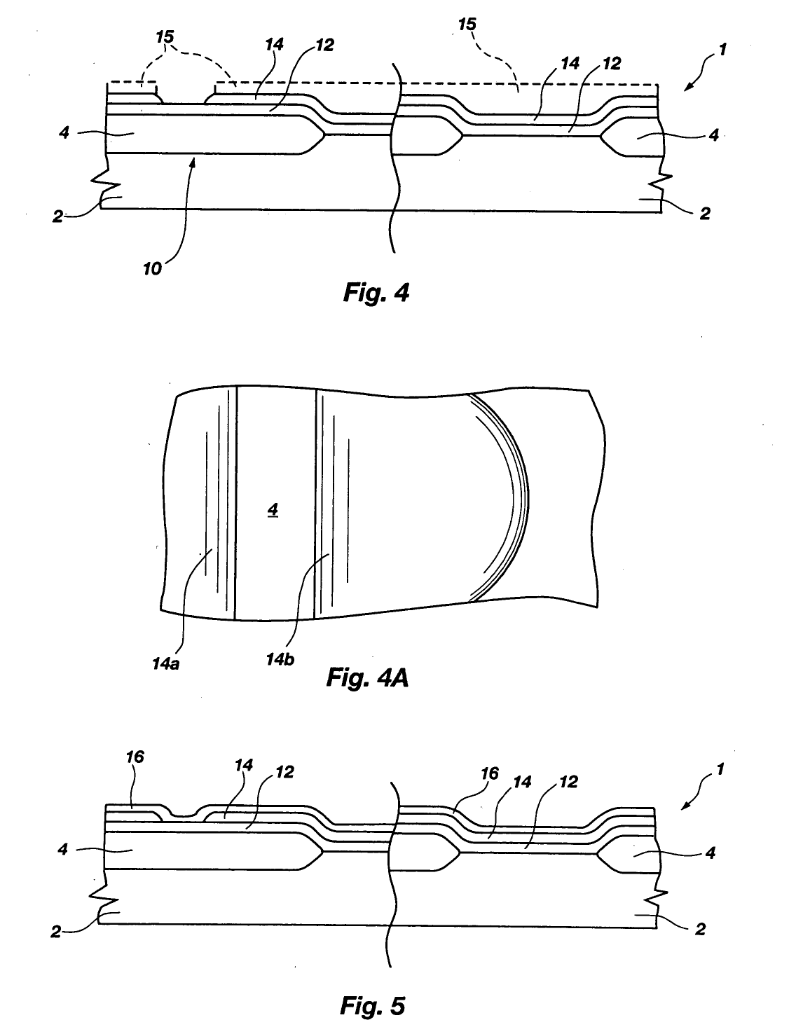

As shown in FIGS. 1 and 2, a semiconductor device 1 upon which a fuse is to be fabricated is provided. Semiconductor device 1 preferably includes a substrate 2 comprising a semiconductor wafer or bulk semiconductor region of a substrate, such as a silicon-on-insulator (“SOI”), silicon-on-glass (“SOG”), silicon-on-ceramic (“SOC”), or silicon-on-sapphire (“SOS”) structure. More preferably, substrate 2 comprises a silicon wafer lightly doped with a p-type dopant.

An insulative structure 4, such as a field oxide layer, may be disposed over a surface of substrate 2 by any suitable process known in the art. As known in the art, regions of substrate 2 that are exposed through the field oxide that comprises the illustrated insulative structure 4 may be referred to as active regions 8. Various structures of a semiconductor device, such as diffusion regions (e.g., the source and drain regions of a transistor) and conductive elements (e.g., the gate of a transistor), may be fabricated at or upon active regions 8. Conductive elements, gate structures and other structures may also be fabricated over insulative structures 4, such as the field oxide regions of semiconductor device 1. Alternatively, insulative structure 4 may comprise a glass (e.g., borophosphosilicate glass (“BPSG”), phosphosilicate glass (“PSG”) or borosilicate glass (“BSG”)), silicon nitride, or other electrically insulative material, which may be disposed upon substrate 2 and patterned as known in the art.

As depicted in FIG. 3, a layer 12 of dielectric material may be disposed over substrate 2 and, optionally, over insulative structure 4. Any dielectric material that may be employed as a gate dielectric, such as a silicon oxide, a glass (e.g., BPSG, PSG, BSG, etc.), organic dielectric materials, a silicon oxynitride, or a silicon nitride, or a composite layer of any combination of these materials can be used as layer 12. Preferably, layer 12 comprises silicon oxide, and may be fabricated by thermally oxidizing substrate 2 or by known tetraethylorthosilicate (“TEOS”) deposition processes. Layer 12 may be disposed substantially over the exposed regions of substrate 2. Alternatively, layer 12 may also extend, at least partially, over insulative structure 4 (e.g., if layer 12 is deposited rather than thermally grown).

A layer 14 of conductive material, such as polysilicon, may be disposed over layer 12 of dielectric material and over insulative structure 4. Layer 14 may be fabricated by any suitable deposition method known in the art, such as by chemical vapor deposition. If layer 14 comprises polysilicon, the polysilicon of layer 14 may be conductively doped with any suitable dopant and by any suitable ion implantation process known in the art. Alternatively, the polysilicon of layer 14 can be in-situ doped during deposition by including a gas containing the desired dopant in the deposition atmosphere.

As shown in FIG. 4, layer 14 or selected regions thereof may be patterned. For example, only the regions of layer 14 that are disposed adjacent insulative structure 4 may be patterned. Alternatively, the regions of layer 14 that overlie active regions 8 may also be patterned. Layer 14 may be patterned by any suitable method known in the art. Preferably, layer 14 is patterned by disposing a mask thereover and patterning layer 14 through the mask. In an exemplary patterning process, a layer of photoresist is disposed over layer 14 and exposed and developed, and portions thereof removed to define a photomask 15 (shown by the dotted line) adjacent layer 14. The regions of layer 14 that are exposed through photomask 15 may be removed by known processes, such as by using any suitable etching process and etchant that will remove the material or materials of layer 14 without substantially affecting the underlying insulative structure 4 or gate dielectric to expose a portion of underlying isolation region 10. The polysilicon of layer 14 may be patterned in separate processes to separately define spaced apart regions 14a and 14b of polysilicon to be disposed adjacent fuse 22 and the polysilicon of gate 20 (see FIG. 6). Preferably, an isotropic etchant and etching process are employed to remove the exposed portions of layer 14 in order to define spaced apart regions 14a and 14b of polysilicon. An isotropic, or wet, etch process is preferred over an anisotropic, or dry, etch process since anisotropic etching of layer 14 will likely result in substantially vertical edges of layer 14 relative to the plane of layer 14 (i.e., the plane of layer 14 being horizontal), which can cause a lack of conformality as a layer of material is disposed over the remaining portions of layer 14, such as spaced apart regions 14a and 14b. Upon removing selected regions of layer 14, the underlying structures, such as insulative structure 4 and layer 12 of dielectric material from which a gate dielectric is to be subsequently defined, are exposed through the remaining regions of layer 14. Mask 15 may then be removed by known processes and semiconductor device 1 washed. Any exposed portions of layer 12 may also be removed by known processes, such as by etching. These exposed portions of layer 12 may be removed either prior to or following the removal of mask 15.

Referring now to FIG. 5, a layer 16 of a conductive material, such as a metal silicide (e.g., tungsten silicide), may be disposed over layer 14 and the underlying structures or layers that are exposed through the remaining regions of layer 14. Layer 16 may comprise any conductive material known in the art that has both a lower resistance and a lower melting point than the material or materials of layer 14.

Layer 16 may be formed by any suitable process known in the art. For example, when tungsten silicide is employed as layer 16, the tungsten silicide may be disposed upon the semiconductor device by any process known in the art to yield the desired physical and chemical characteristics, such as chemical vapor deposition or physical vapor deposition (“PVD”) (e.g., co-sputtering). An exemplary tungsten silicide deposition process that may be employed in the method of the present invention is disclosed in U.S. Pat. No. 5,231,056, which issued to Gurtej S. Sandhu on Jul. 27, 1993, the disclosure of which is hereby incorporated in its entirety by this reference. If titanium silicide is employed as the metal silicide of layer 16, known titanium silicide deposition processes, such as those disclosed in U.S. Pat. Nos. 5,240,739, 5,278,100, and 5,376,405, each of which issued to Trung T. Doan et al. on Aug. 31, 1993, Jan. 11, 1994, and Dec. 27, 1994, respectively, the disclosures of each of which are hereby incorporated by reference in their entireties, may be used to form layer 16. As another example, a layer of metal may be disposed adjacent a layer or structure comprising silicon or polysilicon. The metal may then be annealed, by known processes, to the adjacent silicon or polysilicon to form layer 16.

As depicted in FIG. 6, layer 16 may be patterned by any suitable process known in the art to define a gate 20 and a fuse 22. Gate 20 and fuse 22 may be defined from layer 16 substantially simultaneously or separately in time. Any previously unpatterned portions of layers 14 and 12 may also be patterned, as necessary, to further define gate 20 and fuse 22. While patterning layer 16 and, more specifically, while defining fuse 22 therefrom, regions of layer 16 that overlie the regions of layer 14 disposed on insulative structure 4 are preferably configured as terminal regions 24 and 25. The region of layer 16 disposed between terminal regions 24 and 25, which region is disposed directly on either insulative structure 4 or on layer 12 of dielectric material, if such was disposed or remains on insulative structure 4, and which is also referred to herein as an insulative structure, is configured as the central region 26 of fuse 22. Central region 26 is preferably narrower in width or has a lesser material volume than terminal regions 24 and 25.

Known processes, such as the disposal of a mask 21 over layer 16 and the removal of portions of layer 16 that are exposed through mask 21, may be employed to pattern layer 16. For example, mask 21 can be disposed adjacent layer 16 by disposing a quantity of a photoresist material adjacent layer 16 (e.g., by spin-on processes) and by exposing and developing selected regions of the photoresist material. The portions of layer 16 that are exposed through mask 21 may be removed by any suitable etching process and with any suitable etchant of the material of layer 16 to define gate 20 and fuse 22. Preferably, if removal of any structures or layers that underlie layer 16 is not desired, the etching process and etchant will not substantially remove the material or materials of these structures or layers. Anisotropic etchants and etching processes are preferably employed to pattern layer 16. Regions of layers 14 and 12 that are exposed through the remaining portions of layer 16 may, however, be patterned by known processes to further define gate 20 or fuse 22.

Once fuse 22 and gate 20 have been fabricated, further processing of the desired semiconductor device can proceed. For example, diffusion regions, such as source and drain regions of a transistor, can be formed by implanting selected regions of substrate 2, preferably those regions adjacent each side of gate 20, with a desired dopant. Contacts 30 (see FIG. 7) may also be fabricated in communication with terminal regions 24 and 25 of fuse 22, as well as above the source and drain regions of substrate 2, by known processes. Other structures or layers may also be fabricated on semiconductor device 1 by known processes.

Referring again to FIGS. 7 and 8, a method of using the fuse 22 of the present invention is described. A current is drawn through fuse 22 by means of contacts 30 or other conductive elements in communication with terminal regions 24 and 25 of fuse 22. When a sufficient amount of current flows through fuse 22, the temperature of fuse 22 increases. As polysilicon is disposed adjacent each of terminal regions 24 and 25 of fuse 22, if, upon applying a programming current to fuse 22, one of terminal regions 24 or 25 of fuse 22 becomes discontinuous, the adjacent polysilicon region 14a or 14b will continue to communicate the current. Since polysilicon has substantially the same resistance as many metal silicides, the current applied to the fuse will not be significantly altered if one of the terminal regions becomes discontinuous. Moreover, since polysilicon is disposed adjacent only terminal regions 24 and 25 of fuse 22, the combination of the adjacent layers of polysilicon and metal silicide impart terminal regions 24 and 25 with a much greater conductive material volume than central region 26 of fuse 22. Accordingly, upon application of an electrical current, such as the programming current, the current density will be much greater in central region 26 than at terminal regions 24 and 25. Consequently, upon application of an electrical current to fuse 22, the temperature of central region 26 thereof increases more quickly than the temperature of terminal regions 24 and 25. Thus, central region 26 of fuse 22 will likely become discontinuous, or “blow,” before terminal regions 24 and 25 thereof. As central region 26 of fuse 22 becomes discontinuous, current flow across fuse 22 is interrupted.

Of course, as is well known and may be readily determined by those of ordinary skill in the art, the relative dimensions of each region of fuse 22, the material or materials of fuse 22, the dimensions of spaced apart regions 14a and 14b, and other factors dictate the amount of current that is required to cause central portion 26 to “blow” or otherwise become discontinuous before either of terminal regions 24 or 25 Ablow” or otherwise become discontinuous. With current no longer flowing across fuse 22, an open circuit is created since central region 26 is disposed directly adjacent a substantially non-conductive structure or layer.

Further enhancements to the above disclosed method could be performed. For example, the fuse of the present invention could be fabricated either independently or concurrently with the fabrication of semiconductor devices other than a transistor gate.

Having thus described in detail the preferred embodiments of the present invention, it is to be understood that the invention defined by the appended claims is not to be limited by particular details set forth in the above description, as many apparent variations thereof are possible without departing from the spirit or scope thereof.

What is claimed is:

1. A method for programming a fuse, comprising:
applying a programming current to a terminal of a fuse including:
a first layer comprising a metal silicide; and
a second layer comprising another conductive material,
the first and second layers collectively comprising a first quantity of conductive material; and
conveying the programming current from the terminal to a programmable region of the fuse, the programmable region comprising a second quantity of metal silicide, the programming current causing the metal silicide of the programmable region to agglomerate or melt without causing agglomeration or melting of the metal silicide of the terminal.

2. The method of claim 1, wherein conveying comprises conveying the programming current from the first quantity of conductive material to a lesser, second quantity of conductive material.

3. The method of claim 2, wherein conveying comprises heating the second quantity of conductive material.

4. The method of claim 3, wherein heating renders the second quantity of conductive material discontinuous.

5. The method of claim 1, wherein applying the programming current comprises applying a programming current that is insufficient to render the second layer of the terminal discontinuous.

6. The method of claim 5, wherein applying the programming current comprises applying a programming current that, with the first quantity of conductive material, is insufficient to render the first layer of the terminal discontinuous.

7. The method of claim 1, wherein conveying comprises conveying the programming current to a programmable region that cannot be programmed with a laser.

8. The method of claim 7, wherein conveying comprises conveying the programming current to a programmable region having dimensions that are too small for laser programming.

9. A fuse, comprising:
at least two terminal regions located on a dielectric structure, each terminal region including:
a first layer comprising a metal silicide; and
a second layer comprising another conductive material that remains electrically in-tact when the metal silicide of the first layer becomes discontinuous,
the first layer of each terminal region comprising a first quantity of metal silicide; and
a programmable region that cannot be programmed with a laser located between the at least two terminal regions and comprising a second quantity of metal silicide, the second quantity being configured to be rendered discontinuous more readily than the first quantity.

10. The fuse of claim 9, wherein the programmable region has dimensions that prevent programming thereof with a laser.

11. The fuse of claim 9, wherein the programmable region is configured to agglomerate or melt when a programming current is applied thereto.

12. The fuse of claim 11, wherein the first layer of each terminal is configured not to agglomerate or melt when the programming current is applied thereto.

13. A method for fabricating a fuse, comprising:
forming a layer comprising dielectric material over a semiconductor substrate;
forming a layer comprising conductive material over the layer comprising dielectric material;
patterning the layer comprising conductive material to form at least terminals of at least one fuse and a conductive layer of at least one transistor gate;
removing dielectric material of the layer comprising dielectric material at least from between terminals of the at least one fuse;
forming another layer comprising conductive material over the layer comprising conductive material and in contact with a structure located beneath the layer comprising dielectric material; and
patterning at least the another layer to form the terminals and a programmable element of the at least one fuse and another conductive layer of the at least one transistor gate.

14. The method of claim 13, further comprising:
removing exposed regions of the layer comprising dielectric material after patterning at least the another layer to form at least one gate dielectric.

15. The method of claim 14, further comprising:
forming a dielectric cap on and side walls spacers laterally adjacent to the at least one transistor gate after patterning at least the another layer.

16. The method of claim 13, wherein patterning the layer comprising conducive material comprises forming at least two spaced apart regions comprising the conductive material.

17. The method of claim 13, wherein removing dielectric material comprises removing all exposed portions of the layer comprising dielectric material.
